(19) United States
(12) Patent Application Publication
(10) Pub. No.: US 2017/0032988 A1
(43) Pub. Date: Feb. 2, 2017

(54) PLASMA TREATMENT APPARATUS

(71) Applicant: SAMSUNG ELECTRONICS CO., LTD., Suwon-si (KR)

(72) Inventors: Myoung Soo PARK, Seongnam-si (KR); Yoshihisa HIRANO, Suwon-si (KR); Jongwoo SUN, Seoul (KR); Sangrok OH, Yongin-si (KR)

(21) Appl. No.: 15/163,715

(22) Filed: May 25, 2016

(30) Foreign Application Priority Data
Jul. 29, 2015 (KR) 10-2015-0107295

(51) Int. Cl. H01L 21/67; C23C 16/50; C23C 16/455; H01J 37/32

(52) U.S. Cl. CPC H01L 21/67069; H01J 37/32009; C23C 16/50; C23C 16/455; H01J 37/3244; H01J 2237/334

(57) ABSTRACT

A plasma treatment apparatus including a chamber in which a plasma treatment process is to be performed; and a plasma protection layer on an inner surface of the chamber, wherein the inner surface of the chamber has a center-line average roughness of 0.5 μm or less.

### CROSS-REFERENCE TO RELATED APPLICATION

Korean Patent Application No. 10-2015-0107295, filed on Jul. 29, 2015, in the Korean Intellectual Property Office, and entitled: “Plasma Treatment Apparatus,” is incorporated by reference herein in its entirety.

### BACKGROUND

1. Field

Embodiments relate to a plasma treatment apparatus.

2. Description of the Related Art

Generally, a semiconductor device may be manufactured using a plurality of unit processes. The unit processes may include, e.g., a deposition process, a diffusion process, a thermal treatment process, a photolithography process, a polishing process, an etching process, an ion implantation process, or a cleaning process.

### SUMMARY

Embodiments are directed to a plasma treatment apparatus.

The embodiments may be realized by providing a plasma treatment apparatus including a chamber in which a plasma treatment process is to be performed; and a plasma protection layer on an inner surface of the chamber, wherein the inner surface of the chamber has a center-line average roughness of 0.5 μm or less.

The center-line average roughness of the inner surface of the chamber may be equal to or greater than 0.01 μm.

The chamber may include a lower housing; and an upper housing on the lower housing, the plasma protection layer may include a first ceramic and is on an inner bottom surface of the upper housing, and the inner bottom surface of the upper housing may face an inner top surface of the lower housing.

The upper housing may include a window, and a lower surface of the window may be at the inner bottom surface of the upper housing.

The window may include a second ceramic, the second ceramic being different from the first ceramic, and the second ceramic may include aluminum oxide.

The lower housing may include a wall liner under an edge of the inner bottom surface of the upper housing, and the plasma protection layer may be on an inner sidewall and a top surface of the wall liner.

The wall liner may include a metal that is different from that of the first ceramic, and the metal may include aluminum.

The lower housing may include an electrostatic chuck at which a substrate is receivable; and a ring member surrounding an edge of the electrostatic chuck, and the plasma protection layer may be on an outer sidewall and a top surface of the ring member.

The ring member may include a third ceramic, the third ceramic including a same material as the first ceramic, and the third ceramic may include yttrium oxide.

The outer sidewall and the top surface of the ring member may have a center-line average roughness of 0.01 μm to 0.09 μm.

The embodiments may be realized by providing a plasma treatment apparatus including a base material; and a plasma protection layer on the base material, wherein a surface of the base material has a center-line average roughness of 0.01 μm to 0.5 μm.

The plasma protection layer may include yttrium oxide.

The base material may include a window formed of aluminum oxide.

The base material may include a wall liner formed of aluminum.

The base material may include a ring member formed of a ceramic.

The embodiments may be realized by providing a plasma treatment apparatus including a chamber including a space in which a plasma treatment process is to be performed; and a plasma protection layer on surfaces of the chamber that face the space, wherein the surfaces of the chamber that face the space have a center-line average roughness of 0.5 μm or less.

The center-line average roughness of the surfaces of the chamber that face the space may be equal to or greater than 0.01 μm.

The center-line average roughness of some surfaces of the chamber that face the space may be different from the center-line average roughness of some other surfaces of the chamber that face the space.

The plasma protection layer may include a ceramic material.

The ceramic material may include yttrium oxide, aluminum oxide, yttrium fluoride, yttrium oxyfluoride, diamond, or graphite.

### BRIEF DESCRIPTION OF THE DRAWINGS

Features will be apparent to those of skill in the art by describing in detail exemplary embodiments with reference to the attached drawings in which:

FIG. 1 illustrates a schematic view of a semiconductor manufacturing system according to an embodiment.

FIG. 2 illustrates a schematic view of an etching apparatus of FIG. 1 according to an embodiment.

FIG. 3 illustrates an enlarged cross-sectional view of a window and a plasma protection layer in a portion ‘A’ of FIG. 2 according to an embodiment.

FIG. 4 illustrates a graph of an etching rate of the plasma protection layer in relation to a center-line average roughness of a lower surface of the window of FIG. 3.

FIG. 5 illustrates a graph of a bonding strength between the plasma protection layer and the window in relation to the center-line average roughness of the lower surface of the window of FIG. 3.

FIG. 6 illustrates an enlarged cross-sectional view of a wall liner and the plasma protection layer in a portion ‘B’ of FIG. 2.

FIG. 7 illustrates an enlarged cross-sectional view of a ring member and the plasma protection layer in a portion ‘C’ of FIG. 2.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another element, it can be directly on the other element, or intervening elements may also be present. Further, it will be understood that when an element is referred to as being “under” another element, it can be directly under, or one or more intervening elements may also be present. In addition, it will also be understood that when an element is referred to as being “between” two elements, it can be the only element between the two elements, or one or more intervening elements may also be present. Like reference numerals refer to like elements throughout.

As used herein, the singular terms “a,” “an” and “the” are intended to include the plural forms as well, unless the context clearly indicates otherwise. As used herein, the term “and/or” includes any and all combinations of one or more of the associated listed items. It will be further understood that the terms “comprises”, “comprising”, “includes” and/or “including”, when used herein, specify the presence of stated steps, elements, and/or components, but do not preclude the presence or addition of one or more other steps, elements, components, and/or groups thereof. Unless otherwise defined, terms ‘a chamber’, ‘plasma’, ‘a protection layer’, and ‘coating’, which will be used herein, have the same meaning as commonly understood by one of ordinary skill in the art.

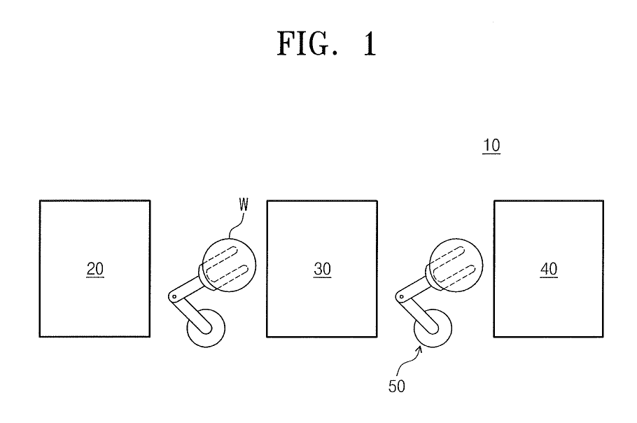

FIG. 1 illustrates a schematic view of a semiconductor manufacturing system 10 according to an embodiment.

Referring to FIG. 1, a semiconductor manufacturing system 10 may perform a unit process on a substrate W. For example, the unit process may include at least one of a deposition process, a photolithography process, or an etching process. In an implementation, the unit process may include at least one of a diffusion process, a thermal treatment process, a polishing process, an ion implantation process, a cleaning process, or an ashing process. According to an embodiment, the semiconductor manufacturing system 10 may include, e.g., a deposition apparatus 20, a photolithography apparatus 30, an etching apparatus 40, and transfer units 50. The deposition apparatus 20 may perform the deposition process. For example, the deposition apparatus 20 may deposit a thin layer on a substrate W. The photolithography apparatus 30 may perform the photolithography process of a photoresist. For example, the photolithography apparatus 30 may form a mask pattern on a substrate W. The etching apparatus 40 may perform the etching process. The etching apparatus 40 may etch a substrate W or thin layer exposed by a mask pattern. The transfer units 50 may transfer a substrate W. The transfer units 50 may be disposed between the deposition apparatus 20 and the photolithography apparatus 30 and between the photolithography apparatus 30 and the etching apparatus 40, respectively. The deposition apparatus 20, the photolithograph apparatus 30, the etching apparatus 40, and the transfer units 50 may be arranged in a line. The semiconductor manufacturing system 10 may sequentially perform the unit processes on substrates W.

According to an embodiment, the deposition apparatus 20 and the etching apparatus 40 may treat substrates W with or by performing a plasma reaction. For example, the deposition apparatus 20 may include a sputtering apparatus. The etching apparatus 40 may include an inductively coupled plasma (ICP) etching apparatus or a capacitively coupled plasma (CCP) etching apparatus.

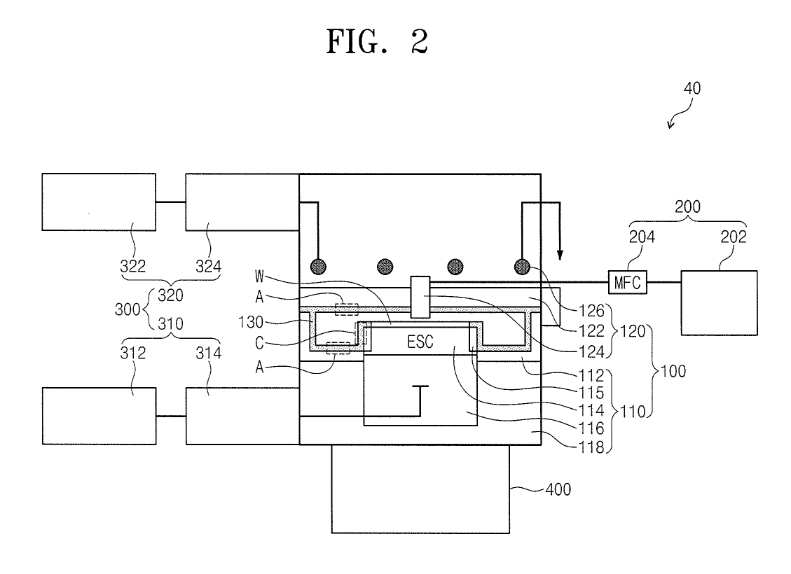

FIG. 2 illustrates a schematic view of the etching apparatus 40 of FIG. 1 according to an embodiment.

Referring to FIG. 2, the etching apparatus 40 may include, e.g., a chamber 100, a gas supply unit 200, a high-frequency supply unit 300, a pumping unit 400, and a plasma protection layer 130. A substrate W may be provided into the chamber 100. The gas supply unit 200 may provide a reaction gas into the chamber 100. The high-frequency supply unit 300 may provide high-frequency power into the chamber 100. The high-frequency power may induce a plasma reaction of the reaction gas. For example, the high-frequency power may convert the reaction gas into plasma. The pumping unit 400 may pump out air or gas existing in the chamber 100, e.g., before and/or after performing the plasma reaction. A substrate W may be etched by the plasma. The plasma protection layer 130 may protect an inner surface (e.g., an inner sidewall) of the chamber 100 from the plasma generated from the reaction gas.

The chamber 100 may provide a space independent of or isolated from the outside of chamber 100, and a substrate W may be loaded into the space of the chamber 100. According to an embodiment, the chamber 100 may include a lower housing 110 and an upper housing 120. A substrate W may be provided on or at the lower housing 110. The lower housing 120 may be disposed on the substrate W and the lower housing 110. For example, the substrate W may be provided on the lower housing 110, and the upper housing 120 may be coupled to the lower housing 110. In an implementation, the lower housing 110 and the upper housing 120 may be vertically separated from each other when the substrate W is loaded and/or unloaded.

According to an embodiment, the lower housing 110 may include a wall liner 112, an electrostatic chuck (ESC) 114, a ring member 115, a lower electrode 116, and a supporting block 118. The wall liner 112 may be coupled to or face an edge of an inner bottom surface of the upper housing 120. The electrostatic chuck 114 may be disposed in the wall liner 112. The electrostatic chuck 114 may receive a substrate W. The reaction gas may flow into a space between the substrate W and the upper housing 120. The ring member 115 may surround an edge of the electrostatic chuck 114. The lower electrode 116 may be disposed under the electrostatic chuck 114. The lower electrode 116 may receive the high-frequency power from the high-frequency supply unit 300. The reaction gas may be concentrated to the substrate W loaded on the electrostatic chuck 114 by high-frequency power. The supporting block 118 may be disposed under the wall liner 112 and the lower electrode 116. In an implementation, the supporting block 118 may be moved by a lifter in an up and down direction (e.g., vertical direction in FIG. 2).

According to an embodiment, the upper housing 120 may include a window 122, a gas nozzle 124, and a plasma antenna 126. The window 122 may be disposed on and/or face the wall liner 112 and the electrostatic chuck 114. The gas nozzle 124 may penetrate a central portion of the window 122. The reaction gas may be provided to the substrate W from the gas nozzle 124. The plasma antenna 126 may be disposed on the window 122. The window 122 may insulate a bottom portion of the plasma antenna 126. The plasma antenna 126 may induce the plasma reaction of the reaction gas by means of the high-frequency power. For example, the reaction gas may be excited into the plasma state by the high-frequency power provided in the plasma antenna 126.

For example, the space of the chamber 110 isolating the substrate W on the electrostatic chuck 114 may be defined by the wall liner 112, the ring member 115, and the window 122.

The pumping unit 400 may be disposed under the lower housing 110, e.g., such that the lower housing 110 is between the pumping unit 400 and the upper housing 120. The pumping unit 400 may exhaust a gas from between the lower housing 110 and the upper housing 120, e.g., after the plasma reaction is performed. For example, the pumping unit 400 may include a vacuum pump.

The gas supply unit 200 may be connected to the upper housing 120. The gas supply unit 200 may include a gas storage part 202 and a mass flow controller (MFC) 204. The gas storage part 202 may store the reaction gas. The mass flow controller 204 may be connected between the gas storage part 202 and the upper housing 120. The mass flow controller 204 may control or adjust a flow rate of the reaction gas provided into the chamber 100.

The high-frequency supply unit 300 may provide the high-frequency power to the lower electrode 116 and the plasma antenna 126. The high-frequency supply unit 300 may include a first high-frequency supply unit 310 and a second high-frequency supply unit 320. The first high-frequency supply unit 310 may be connected to the lower electrode 116. The first high-frequency supply unit 310 may include a first high-frequency generator 312 and a first matcher 314. The first high-frequency generator 312 may generate a first high-frequency power. The first matcher 314 may be connected between the first high-frequency generator 312 and the lower electrode 116. The first matcher 314 may match an impedance of the first high-frequency power. The first high-frequency power may concentrate the reaction gas in a plasma state to the substrate W. The second high-frequency supply unit 320 may be connected to the plasma antenna 126. The second high-frequency supply unit 320 may include a second high-frequency generator 322 and a second matcher 324. The second high-frequency generator 322 may generate a second high-frequency power. The second matcher 324 may be connected between the second high-frequency generator 322 and the plasma antenna 126. The second high-frequency power may activate the plasma reaction of the reaction gas. The second matcher 324 may match impedance of the second high-frequency power. An intensity of the plasma reaction may increase in proportion to a magnitude of the second high-frequency power.

The inner surface of the chamber 100 may be coated with the plasma protection layer 130. According to an embodiment, the window 122, the wall liner 112, and the ring member 115 may be coated with the plasma protection layer 130. The window 122, the wall liner 112, and the ring member 115 may be used as base materials of the plasma protection layer 130, e.g., may serve as a base for the plasma protection layer 130. In an implementation, the window 122, the wall liner 112, and/or the ring member 115 may be formed of materials that are different from each other.

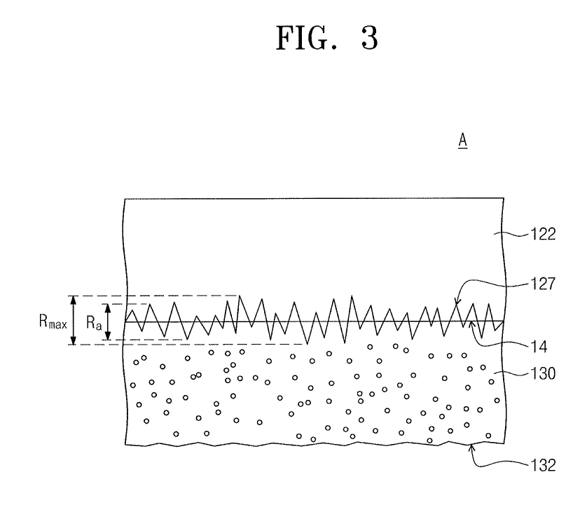

FIG. 3 illustrates an enlarged cross-sectional view of the window 122 and the plasma protection layer 130 in a portion ‘A’ of FIG. 2 according to an embodiment. Referring to FIG. 3, the plasma protection layer 130 may be formed on a lower surface 127 (e.g., inwardly facing surface) of the window 122 by a coating method. In an implementation, the plasma protection layer 130 may include a first ceramic material or first ceramic. In an implementation, the plasma protection layer 130 may include yttrium oxide (Y₂O₃). In an implementation, the plasma protection layer 130 may include at least one of aluminum oxide (Al₂O₃), yttrium fluoride (YF), yttrium oxyfluoride (YₓO_{y}F_{z}, in which x=1, y=1 or 2, and z=1 or 2; YOF, YO₂F, or YOF₂), diamond, or graphite. The plasma protection layer 130 may have a thickness of about 1 μm to about 1 mm.

According to an embodiment, the window 122 may include a dielectric and/or a second ceramic. In an implementation, the window 122 may include a different, e.g., oxide, from the plasma protection layer 130. For example, the window 122 may include aluminum oxide.

A surface roughness of the window 122 and/or a surface roughness of the plasma protection layer 130 may affect an etching rate of the plasma protection layer 130. According to an embodiment, the etching rate of the plasma protection layer 130 may increase as a surface roughness of a bottom surface 132 (e.g., inwardly facing surface) of the plasma protection layer 130 increases. The bottom surface 132 of the plasma protection layer 130 may be exposed in or at the inner space of the chamber 100. The surface roughness may be determined depending on a coating condition of the plasma protection layer 130. For example, the surface roughness of the bottom surface 132 of the plasma protection layer 130 may be proportional to or may vary in relation to a surface roughness of the lower surface 127 of the window 122. For example, the surface roughness of the bottom surface 132 of the plasma protection layer 130 may increase as the surface roughness of the lower surface 127 of the window 122 increases. This is because the surface roughness of the lower surface 127 of the window 122 may be projected or transferred to the bottom surface 132 of the plasma protection layer 130.

A surface roughness may include a center-line average roughness Rₐ and the maximum roughness Rₘₐₓ. The center-line average roughness Rₐ of the window 122 may be defined as an average value of absolute values of lengths from a center line 14 (illustrated in FIG. 3) to valleys and peaks of the lower surface 127 of the window 122. The maximum roughness Rₘₐₓ may be defined as a length between two parallel lines passing through the highest point and the lowest point, respectively.

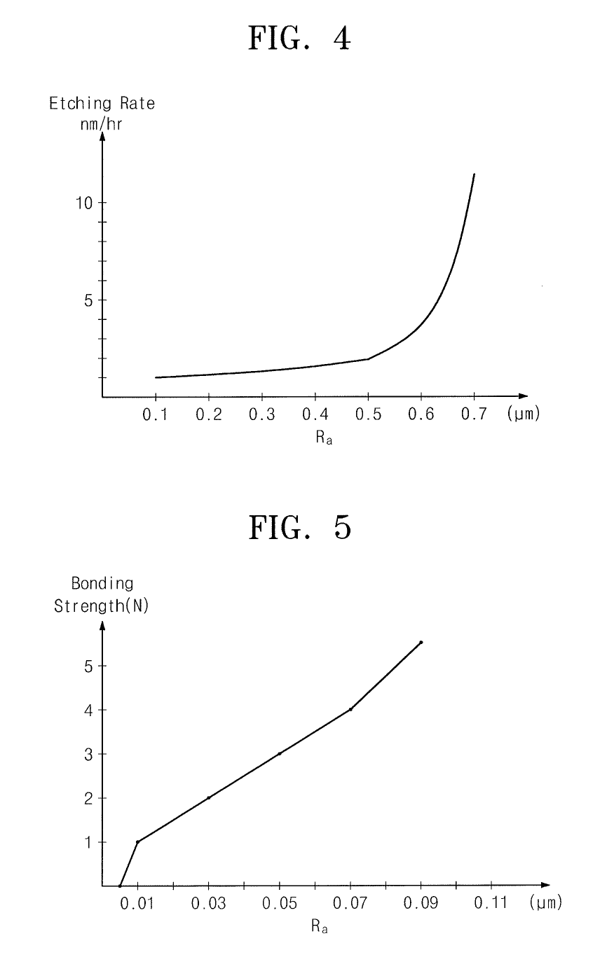

FIG. 4 illustrates a graph of the etching rate of the plasma protection layer 130 in relation to the center-line average roughness Rₐ of the lower surface 127 of the window 122 of FIG. 3.

Referring to FIG. 4, the etching rate of the plasma protection layer 130 may be proportional to or may vary in relation to the center-line average roughness Rₐ of the lower surface 127 of the window 122. According to an embodiment, the lower surface 127 of the window 122 may have a center-line average roughness Rₐ of about 0.5 μm or less. The lower surface 127 of the window 122 may have a maximum roughness Rₘₐₓ of 10 μm. For example, when the lower surface 127 has the center-line average roughness Rₐ of 0.1 μm to 0.5 [2m, the plasma protection layer 130 may be slowly etched, e.g., at an etching rate of only about 1 nm/hr to about 2 nm/hr, as illustrated in FIG. 4. If the lower surface 127 were to have the center-line average roughness Rₐ greater than 0.5 μm and equal to or less than 0.7 μm, the plasma protection layer 130 would be rapidly etched, e.g., at an etching rate greater than about 2 nm/hr and equal to or less than about 10 nm/hr, as illustrated in FIG. 4. The plasma protection layer 130 etched at the high etching rate may act as a contamination source of particle defects (e.g., on the wafer W being processed). As a result, the window 122 according to an embodiment may have the center-line average roughness Rₐ of about 0.5 μm or less, and thus the etching rate of the plasma protection layer 130 may be reduced to reduce or minimize the particle defects. In an implementation, the window 122 may include aluminum oxide, and the plasma protection layer 130 may include yttrium oxide having a thickness of about 10 μm. The reaction gas may include SF₆. The second high-frequency power may be about 1 KW.

Referring again to FIG. 3, the surface roughness of the lower surface 127 of the window 122 may be proportional to or have an effect on a surface bonding strength (hereinafter, referred to as ‘a bonding strength’) between the window 122 and the plasma protection layer 130. For example, the bonding strength between the window 122 and the plasma protection layer 130 may increase as the surface roughness of the lower surface 127 of the window 122 increases. This is because a contact area of the window 122 and the plasma protection layer 130 increases as the surface roughness increases. The bonding strength between the window 122 and the plasma protection layer 130 may decrease as the surface roughness of the lower surface 127 of the window 122 decreases.

FIG. 5 illustrates a graph of a bonding strength between the plasma protection layer 130 and the window 122 in relation to the center-line average roughness Rₐ of the lower surface 127 of the window 122 of FIG. 3.

Referring to FIG. 5, the bonding strength between the plasma protection layer 130 and the window 122 may be proportional to or may vary in relation to the center-line average roughness Rₐ of the lower surface 127 of the window 122. The contact area of the window 122 and the plasma protection layer 130 may increase as the center-line average roughness Rₐ of the lower surface 127 of the window 122 increases, and thus the bonding strength between the plasma protection layer 130 and the window 122 may increase. The bonding strength between the plasma protection layer 130 and the window 122 may decrease as the center-line average roughness Rₐ of the lower surface 127 of the window 122 decreases. According to an embodiment, the lower surface 127 of the window 122 may have the center-line average roughness Rₐ of about 0.01 μm or more. As described above, the window 122 may include aluminum oxide, and the plasma protection layer 130 may include yttrium oxide having a thickness of about 10 μm.

The bonding strength between the plasma protection layer 130 and the window 122 may be measured depending on a magnitude of the second high-frequency power used to generate the plasma. The magnitude of the second high-frequency power may range from 1 KW to 1 MW. For example, if the lower surface 127 of the window 122 were to have a center-line average roughness Rₐ of about 0.005 μm or less, the plasma protection layer 130 could be separated from the window 122. The separated plasma protection layer 130 may for particles, e.g., particulate contaminants. In an implementation, the window 122 according to an embodiment may have the center-line average roughness Rₐ of about 0.01 μm or more, and it is possible to minimize particle contamination caused by the plasma protection layer 130 being separated from the window 122. For example, the lower surface 127 of the window 122 may have the center-line average roughness Rₐ of about 0.01 μm to about 0.5 μm.

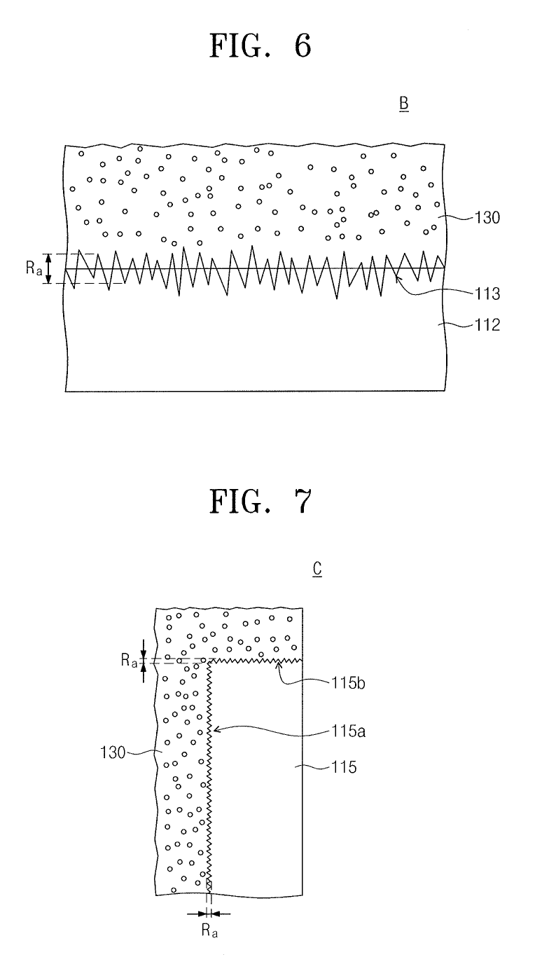

FIG. 6 illustrates an enlarged cross-sectional view of the wall liner 112 and the plasma protection layer 130 in a portion ‘B’ of FIG. 2.

Referring to FIG. 6, the plasma protection layer 130 may be formed on the wall liner 112 by the coating method. In an implementation, the wall liner 112 may include a metal such as aluminum, e.g., elemental or metallic aluminum. In an implementation, the wall liner 112 may include a metal such as stainless steel. In an implementation, the wall liner 112 may include a metal that is different from a metal of the first ceramic of the plasma protection layer 130. The etching rate of the plasma protection layer 130 may be proportional to or may vary in relation to a surface roughness of a top surface 113 (e.g., inwardly facing surface) of the wall liner 112. A bonding strength between the plasma protection layer 130 and the wall liner 112 may be proportional to or may vary in relation to the surface roughness of the top surface 113 of the wall liner 112. According to an embodiment, the top surface 113 of the wall liner 112 may have the same center-line average roughness Rₐ as the lower surface 127 of the window 122. For example, the top surface 113 of the wall liner 112 may have a center-line average roughness Rₐ of about 0.01 μm to about 0.5 μm. If the center-line average roughness Rₐ of the top surface 113 of the wall liner 112 is initially greater than 0.5 μm, the top surface 113 of the wall liner 112 may be ground and/or polished to have the center-line average roughness Rₐ of about 0.01 μm to about 0.5 μm. In an implementation, the top surface 113 of the wall liner 112 may be planarized by a gap-fill material to have the center-line average roughness Rₐ of about 0.01 μm to about 0.5 μm. The gap-fill material may include a different material, e.g., a different ceramic, from the plasma protection layer 130. An inner sidewall of the wall liner 112 may also have the center-line average roughness Rₐ of about 0.01 μm to about 0.5 μm.

FIG. 7 illustrates an enlarged cross-sectional view of the ring member 115 and the plasma protection layer 130 in a portion ‘C’ of FIG. 2.

Referring to FIG. 7, an outer sidewall 115a of the ring member 115 may be coated with the plasma protection layer 130. A top surface 115b of the ring member 115 may also be coated with the plasma protection layer 130. According to an embodiment, the ring member 115 may include a ceramic. For example, the ring member 115 may include yttrium oxide or aluminum oxide. According to an embodiment, a center-line average roughness Rₐ of the outer sidewall 115a and the top surface 115b of the ring member 115 may be smaller than the center-line average roughness Rₐ of the lower surface 127 of the window 122. An amount of the plasma concentrated to or at the ring member 115 may be greater than the amount of the plasma concentrated to the window 122 due to the first high-frequency power, and the outer sidewall 115a and the top surface 115b of the ring member 115 may be more planarized than the lower surface 127 of the window 122. For example, the outer sidewall 115a and the top surface 115b of the ring member 115 may have the center-line average roughness Rₐ of about 0.01 μm to about 0.09 μm. For example, the plasma protection layer 130 on the outer sidewall 115a and the top surface 115b of the ring member 115 may have a greater etch resistance due to the lower center-line average roughness Rₐ of the outer sidewall 115a and the top surface 115b of the ring member 115.

By way of summation and review, a deposition process and/or an etching process (among unit processes for manufacturing a semiconductor device) may be performed using a plasma reaction. A reaction gas on a substrate may be uniformly mixed by means of the plasma reaction. Alternatively, a linear movement characteristic of the reaction gas may be increased by means of the plasma reaction. The plasma reaction could damage an inner sidewall of a chamber. For example, particles could be generated from the damaged inner sidewall of the chamber, and the generated particles could cause defects of the deposition process and the etching process.

As described above, in the plasma treatment apparatus according to embodiments, the inner surface of the chamber may be coated with the plasma protection layer. The inner surface of the chamber may be planarized to have the center-line average roughness of 0.5 μm or less. The plasma protection layer may be substantially flat. The etching rate of the flat plasma protection layer may be lower than that of a rough plasma protection layer. The particle defects may be minimized by the flat plasma protection layer having the low etching rate.

The embodiments may provide a plasma treatment apparatus capable of minimizing particle defects.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A plasma treatment apparatus, comprising:
a chamber in which a plasma treatment process is to be performed; and
a plasma protection layer on an inner surface of the chamber,
wherein the inner surface of the chamber has a center-line average roughness of 0.5 μm or less.

2. The plasma treatment apparatus as claimed in claim 1, wherein the center-line average roughness of the inner surface of the chamber is equal to or greater than 0.01 μm.

3. The plasma treatment apparatus as claimed in claim 1, wherein:
the chamber includes:
a lower housing; and
an upper housing on the lower housing,
the plasma protection layer includes a first ceramic and is on an inner bottom surface of the upper housing, and
the inner bottom surface of the upper housing faces an inner top surface of the lower housing.

4. The plasma treatment apparatus as claimed in claim 3, wherein:
the upper housing includes a window, and
a lower surface of the window is at the inner bottom surface of the upper housing.

5. The plasma treatment apparatus as claimed in claim 4, wherein:
the window includes a second ceramic, the second ceramic being different from the first ceramic, and
the second ceramic includes aluminum oxide.

6. The plasma treatment apparatus as claimed in claim 3, wherein:
the lower housing includes a wall liner under an edge of the inner bottom surface of the upper housing, and
the plasma protection layer is on an inner sidewall and a top surface of the wall liner.

7. The plasma treatment apparatus as claimed in claim 6, wherein:
the wall liner includes a metal that is different from that of the first ceramic, and
the metal includes aluminum.

8. The plasma treatment apparatus as claimed in claim 3, wherein:
the lower housing includes:
an electrostatic chuck at which a substrate is receivable; and
a ring member surrounding an edge of the electrostatic chuck, and
the plasma protection layer is on an outer sidewall and a top surface of the ring member.

9. The plasma treatment apparatus as claimed in claim 8, wherein:
the ring member includes a third ceramic, the third ceramic including a same material as the first ceramic, and
the third ceramic includes yttrium oxide.

10. The plasma treatment apparatus as claimed in claim 8, wherein the outer sidewall and the top surface of the ring member have a center-line average roughness of 0.01 μm to 0.09 μm.

11. A plasma treatment apparatus, comprising:
a base material; and
a plasma protection layer on the base material, wherein a surface of the base material has a center-line average roughness of 0.01 μm to 0.5 μm.

12. The plasma treatment apparatus as claimed in claim 11, wherein the plasma protection layer includes yttrium oxide.

13. The plasma treatment apparatus as claimed in claim 11, wherein the base material includes a window formed of aluminum oxide.

14. The plasma treatment apparatus as claimed in claim 11, wherein the base material includes a wall liner formed of aluminum.

15. The plasma treatment apparatus as claimed in claim 11, wherein the base material includes a ring member formed of a ceramic.

16. A plasma treatment apparatus, comprising:
a chamber including a space in which a plasma treatment process is to be performed; and
a plasma protection layer on surfaces of the chamber that face the space, wherein the surfaces of the chamber that face the space have a center-line average roughness of 0.5 μm or less.

17. The plasma treatment apparatus as claimed in claim 16, wherein the center-line average roughness of the surfaces of the chamber that face the space is equal to or greater than 0.01 μm.

18. The plasma treatment apparatus as claimed in claim 17, wherein the center-line average roughness of some surfaces of the chamber that face the space is different from the center-line average roughness of some other surfaces of the chamber that face the space.

19. The plasma treatment apparatus as claimed in claim 16, wherein the plasma protection layer includes a ceramic material.

20. The plasma treatment apparatus as claimed in claim 19, wherein the ceramic material includes yttrium oxide, aluminum oxide, yttrium fluoride, yttrium oxyfluoride, diamond, or graphite.
